(19) United States
(12) Patent Application Publication
(10) Pub. No.: US 2019/0165331 A1
(43) Pub. Date: May 30, 2019

(54) BENDING FIXTURE

(71) Applicant: Wuhan China Star Optoelectronics Semiconductor Display Technology Co., Ltd., Wuhan (CN)

(72) Inventor: Lun SHANG, Shenzhen (CN)

(21) Appl. No.: 16/024,285

(22) Filed: Jun. 29, 2018

Related U.S. Application Data
(63) Continuation of application No. PCT/CN2018/076458, filed on Feb. 12, 2018.

(30) Foreign Application Priority Data
Nov. 27, 2017 (CN) 201711206063.2

(51) Int. Cl. H01L 51/56; H01L 51/00; B21D 7/02; B21J 13/03

(52) U.S. Cl. CPC H01L 51/56; H01L 51/0097; H01L 2251/5338; B21J 13/03; B21D 7/021

(57) ABSTRACT

The invention provides a bending fixture, applicable to bending flexible OLED display, comprising: a support rack, a concave mold, a convex mold, and a pressing handle. The support rack and the pressing handle are used for fixing the concave mold and the convex mold, respectively, so that the concave mold and the convex mold tightly press the flexible OLED display. Because the corresponding arrangement of the groove on the concave mold and the convex portion on the convex mold, the pairs of matching straight sections provide tight support to the front and back surfaces of the flexible OLED display during bending, comprising bending area, non-bending area and interfacing area between the two areas, so as to guarantee a consist patching of the flexible OLED display while achieving precise bending to improve the bending quality and yield rate of the bending process.

### CROSS REFERENCE TO RELATED APPLICATIONS

This application is a continuing application of PCT Patent Application No. PCT/CN2018/076458, entitled “BENDING FIXTURE”, filed on Feb. 12, 2018, which claims priority to Chinese Patent Application No. CN201711206063.2, filed on Nov. 27, 2017, both of which are hereby incorporated in its entireties by reference.

### BACKGROUND OF THE INVENTION

### 1. Field of the Invention

The present invention relates to the field of display and, in particular, to the field of a bending fixture for flexible OLED display.

### 2. The Related Arts

The flexible organic light-emitting diode (OLED) display, with the advantages of requiring no backlight, large viewing angle, thinness and lightweight, is widely used. In particular, the flexibility makes the screen bendable and shows far more malleable than previous-generation display products, such as, LCDs.

Regarding bending fixtures for the known flexible OLED display, because of the differences in the thicknesses of different flexible OLED displays, and different flexible OLED displays requiring different bending angles and bending radii, most bending fixtures do not have sufficient restrictions on the flexible OLED displays during the bending process in order to be compatible with different thicknesses, bending radii, and bending angle of the flexible OLED displays, which results in uneven patching phenomenon at some areas of the flexible OLED display after bending; especially at the location of the bending junction, which in turn greatly affects the bending quality and yield of flexible OLED displays.

### SUMMARY OF THE INVENTION

The primary object of the present invention is to provide a bending fixture, compatible with multi-size displays and ensuring even patching.

To solve the above technical issue, the present invention provides a bending fixture, applicable to bending flexible OLED display, the bending fixture comprising: a support rack, a concave mold, a convex mold, and a pressing handle; the support rack comprising: a base, a left plate, and a right plate; the base, the left plate, and the right plate collectively forming a receiving cavity for receiving the concave mold; the concave mold being disposed with a groove, the groove comprising: a first straight section, a corner section and a second straight section; the corner section having an arc shape, the first straight section being connected to the corner section and tangent to the corner section, the second straight section being connected to the corner section and tangent to the corner section; an angle between the first straight section and the second straight section being a bending angle of the flexible OLED display; and the convex mold having a convex portion, the convex portion having a third straight section corresponding to the first straight section, a fourth straight section corresponding to the second straight section; and a rounded corner section corresponding to the corner section; the third straight section being connected to the fourth straight section through the rounded corner section; the pressing handle being connected to the convex mold and used to hold the convex mold during bending to ensure that the convex mold extending into the groove and pressed correctly into place.

According to a preferred embodiment of the present invention, the first straight section is parallel to the second straight section, and the arc shape of the corner section is a semicircle.

According to a preferred embodiment of the present invention, the number of the concave mold is a plurality, and the plurality of concave molds have corner sections with different radii, all the plurality of concave molds have appearances matching the shape of the receiving cavity so that each of the plurality of the concave molds can be placed inside the receiving cavity according to the radius corresponding to the bending radius of the flexible OLED display.

According to a preferred embodiment of the present invention, the corner section of the concave mold has a radius of 1 mm-3 mm.

According to a preferred embodiment of the present invention, the groove is disposed at a first plane of the concave mold, and a right-angled edge formed by the groove and the first plane is rounded.

According to a preferred embodiment of the present invention, the groove penetrates through the concave mold; in a groove length direction, the concave mold provides at the first plane an against surface perpendicular to the groove length direction, for pushing against the flexible OLED display during bending to maintain the bending line of the flexible OLED display perpendicular to borders of the OLED display.

According to a preferred embodiment of the present invention, the number of the concave mold is a plurality, and the first straight sections and the second straight sections of the plurality of concave molds form different intersection angle, all the plurality of concave molds have appearances matching the shape of the receiving cavity so that each of the plurality of the concave molds can be placed inside the receiving cavity according to the radius corresponding to the bending radius of the flexible OLED display.

According to a preferred embodiment of the present invention, an enhanced rib is disposed respectively between the base and the left plate, and between the base and the right plate to enhance support.

According to a preferred embodiment of the present invention, the pressing handle comprises a sliding portion, the sliding portion slides on a sliding track disposed on the support rack, the sliding portion drives the convex mold to move in and out with respect to the concave mold to achieve bending and releasing motions.

According to a preferred embodiment of the present invention, the pressing handle comprises a rotation portion, the rotation portion is rotatably connected to a fulcrum on the support rack, and the sliding portion is disposed on the rotation portion, and a bending handle is disposed at a direction extended from the fulcrum extends to a connection point between the sliding portion and the rotation portion.

The bending fixture of the present invention, by collaboration of the convex mold and the concave mold, in particular the first and third straight sections and the second and the fourth straight sections, provides tight support to the front and back surfaces of the flexible OLED display during bending, comprising bending area, non-bending area and interfacing area between the two areas, so as to guarantee a consist patching of the flexible OLED display while achieving precise bending to improve the bending quality and yield rate of the bending process.

### BRIEF DESCRIPTION OF THE DRAWINGS

To make the technical solution of the embodiments according to the present invention, a brief description of the drawings that are necessary for the illustration of the embodiments will be given as follows, Apparently, the drawings described below show only example embodiments of the present invention and for those having ordinary skills in the art, other drawings may be easily obtained from these drawings without paying any creative effort.

FIG. 1 is a schematic view showing the structure of a bending fixture of the present invention.

FIG. 2 is a schematic view showing an embodiment of the bending fixture of the present invention.

### DETAILED DESCRIPTION OF THE PREFERRED EMBODIMENTS

To further explain the technical means and effect of the present invention, the following refers to embodiments and drawings for detailed description. Apparently, the described embodiments are merely some embodiments of the present invention, instead of all embodiments. All other embodiments based on embodiments in the present invention and obtained by those skilled in the art without departing from the creative work of the present invention are within the scope of the present invention.

The terms “comprising” and “having” and any variations thereof appearing in the specification, claims, and drawings of the present application are intended to cover non-exclusive inclusion. For example, a process, method, system, product, or device that includes a series of steps or units is not limited to the listed steps or units, but optionally also includes steps or units not listed, or alternatively, other steps or units inherent to these processes, methods, products or equipment. In addition, the terms “first”, “second” and “third” are used to distinguish different objects and not intended to describe a particular order.

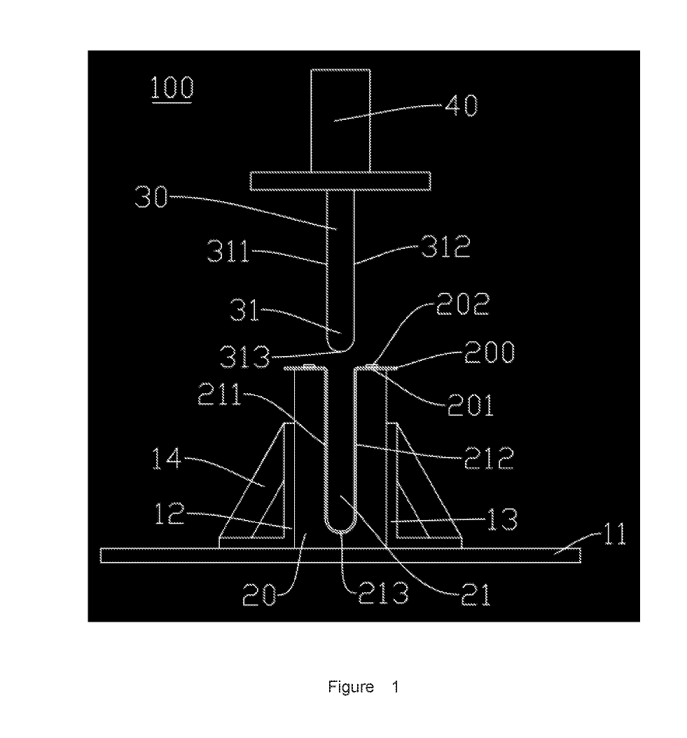

As shown in FIG. 1, the present invention provides a bending fixture 100, comprising: a support rack 10, a concave mold 20, a convex mold 30, and a pressing handle 40. The support rack 10 and the concave mold 20 collaborate, and the convex mold 30 and the pressing handle 40 collaborate. A flexible OLED support 200 is pressed by the collaboration between the concave mold 20 and the convex mold 30 to achieve bending. The support rack 10 comprises: a base 11, a left plate 12, and a right plate 13; the base 11, the left plate 12, and the right plate 13 collectively form a receiving cavity for receiving the concave mold 20. The concave mold 20 is disposed with a groove 21 at a side plane, and the groove 21 comprises: a first straight section 211, a corner section 213 and a second straight section 212; the corner section 213 has an arc shape, the first straight section 211 is connected to the corner section 213 and tangent to the corner section 213, the second straight section 212 is connected to the corner section 213 and tangent to the corner section 213.

Correspondingly, the convex mold 30 is disposed with a convex portion 31 corresponding to the groove. The convex portion 31 has a third straight section 311 corresponding to the first straight section 211, a fourth straight section 312 corresponding to the second straight section 212, and a rounded corner section 313 corresponding to the corner section 213. It should be noted that the third straight section 311 is connected to the rounded corner section 313, and the rounded corner section 313 is connected to the fourth straight section 312. It should be understood that the angle formed between the first straight section 211 and the second straight section 212 is the same as the angle formed between the third straight section 311 and the fourth straight section 312, which is the bending angle of the flexible OLED display after being bended. Correspondingly, the radius of the corner section 213 is the bending radius of the flexible OLED display after bending.

When using the bending fixture of the present invention, the flexible OLED display 200 is placed on the concave mold 20, aligned with the groove 21. Then, the convex mold 30 is pressed into the concave mold 20 by using the pressing handle 40. In other words, the convex portion 31 is pressed into the groove 21 for a tight fit. At this point, the flexible OLED display 200 is pressed between the convex portion 31 and the groove 21, with one side of flexible OLED display 200 tightly pressed against the groove 21 and the other side pressed tightly against the convex portion 31. As such, the flexible OLED display 200 is bended with a preset bending radius matching the corner section 213 through the tight pressure between the corner section 213 and the rounded corner section 313. The bending angle of the flexible OLED display 200 is the same as the angle between the first straight section 211 and the second straight section 212. Moreover, under the pressure of the first straight section 211 and the third straight section 311, and under the pressure of the second straight section 212 and the fourth straight section 312, the two sides of the flexible OLED display 200 within the bending fixture 100 of the present invention are tightly pressed to prevent the flexible OLED display 200 from inconsistent patching phenomenon bending.

It should be noted that the receiving cavity matches the appearance of outer shape of the concave mold 20 so that the concave mold 20 is fixed inside the receiving cavity without displacement to ensure the stability and consistency of the bending operation.

It should be noted that, in some embodiments, the concave mold 20 and the convex mold 30 are made of hard material, such as, metal, to prevent the deformation of the groove 21 and the convex portion 31.

For further compatibility of the bending fixture 100 of the present invention, in accordance with the flexible OLED displays 200 with different bending angles or different bending radii, the concave mold 20 is replaceable. That is, the connection between the concave mold 20 and the receiving cavity is a replaceable connection. Corresponding to different bending angles, a concave mold 20 with an angle between the first straight section 211 and the second straight section 212 is used, and for different bending radii, a corner section 213 with different arc radius is used. Correspondingly, the convex portion 31 must be modify to match the groove 21.

For the bending of flexible OLED display, the flip angle is usually designed as 180° therefore, in some embodiments, the first straight section 211 is parallel to the second straight section 212, and the arc shape of the corner section 213 is a semicircle. Correspondingly, the third straight section 311 and the fourth straight section 312 are parallel. As such, the flexible OLED display 200 is bended to be able to bend for 180°.

In general, the bending radius of the flexible OLED display 200 is between 1 mm-3 mm. Therefore, the corner section 213 of the concave mold 20 has a radius of 1 mm-3 mm.

Before bending operation, the flexible OLED display 200 is placed flatly on a first plane 201 of the concave mold 20, where the groove 21 is disposed at the first plane 201. In the process of flexible OLED display 200 driven by the convex portion 31 into the groove 21, the flexible OLED display 200 is always rubbed with the right-angled edge formed by the intersection between the groove 21 and the first plane 201. If the right-angled edge is too sharp, the surface of the flexible OLED display 200 is easily scratched. Therefore, the right-angled edge is rounded to protect the flexible OLED display 200.

For an embodiment, the groove 21 having a flip angle of 180° has a U-shape cross-section in the longitudinal direction, and the U-shape penetrates through the concave mold 20. In the longitude direction of the groove 21, if the bended area of the flexible OLED display 200 is wider than the concave mold 20, a multi-staged pressing can be used to bend the flexible OLED display 200. On the other hand, the first plane 201 is provided with an against surface 202 perpendicular to the length direction of the groove 21 for pressing against the frame of the flexible OLED display 200 during bending to keep the bend line of the flexible OLED display 200 always perpendicular to the frame of the flexible OLED display 200.

It should be noted that the against surface 202 can be disposed at the end of the groove 21 as long as the against surface 202 is able to press against the frame of the flexible OLED display 200 during bending to achieve the effect.

It should be noted that the against surface 202 can be continuous plane, but preferably a discontinuous plane. One can be disposed at the first straight section 211 or the part of the first plane 201 connecting to the first straight section 211, and another is disposed at the second straight section 212 or the part of the first plane 201 connecting to the second straight section 212. A better effect can be achieved with the two sufficiently apart.

It should be noted that on the condition that the length of the groove 21 can satisfy any size of the flexible OLED display 200, the groove 21 can also be a closed type, with both ends sealed to prevent the dust or particle from entering.

In some embodiments, for further enhancement of supporting the concave mold 20 by the receiving cavity, an enhanced rib 14 is disposed between the base 11 and the left plate 12, and correspondingly, an enhanced rib 14 is disposed between the base 11 and the right plate 13 to enhance support. As such, the left plate 12 and the right plate 13 are prevented from tile and deformation to ensure bending effect.

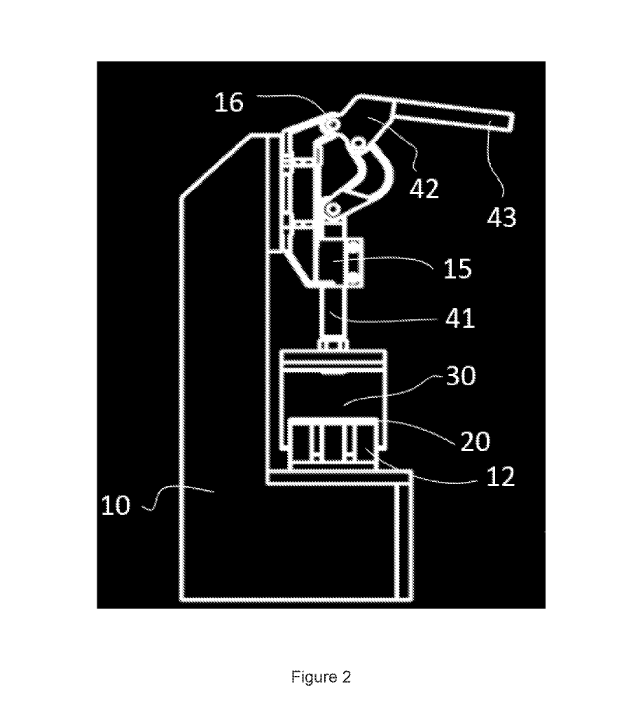

FIG. 2 shows an embodiment. The pressing handle 40 comprises a sliding portion 41. The sliding portion 41 is fixed to the convex mold 30 for driving the convex mold 30 to move in and out with respect to the concave mold 20 to achieve bending and releasing motions. That is, the convex portion 31 is driven by the sliding portion 41 to move into and out of the groove 21 to achieve bending and releasing motions on the flexible OLED display 200. It should be noted that the sliding portion 41 slides on a sliding track 15 disposed on the support rack 10 to drive the convex mold 30 to guarantee the consistency of each motion of the convex mold 30 with respect to the concave mold 20.

In an embodiment, the pressing handle 40 further comprises a rotation portion 42, the rotation portion 42 is rotatably connected to a fulcrum 16 on the support rack 10, i.e., the rotation portion 42 rotates around the fulcrum 16. The sliding portion 41 is disposed on the rotation portion 42, and a bending handle 43 is extended from the rotation portion 42 in a direction extended from the fulcrum 16 extends to a connection point between the sliding portion 41 and the rotation portion 42. During the bending handle 43 rotating the fulcrum 16, the sliding portion 41 slides on the sliding track 15 in a straight line back and forth to drive the convex mold 30 to perform bending and releasing with respect to the concave mold 20. Because of the distance from the fulcrum 16 to the sliding portion 41 is less than the distance from the fulcrum 16 to the bending handle 43, i.e., the arm at the bending handle 43 is larger than the arm at the sliding portion 41, a labor-saving effect can be achieved for pressing or lifting the bending handle 43 during the bending process.

The bending fixture 100 of the present invention, by collaboration of the convex mold 30 and the concave mold 20, in particular the first and third straight sections 211, 311, and the second and the fourth straight sections 212, 312, provides tight support to the front and back surfaces of the flexible OLED display 200 during bending. With the auxiliary collaboration of the corner section 213 and the rounded corner section 313, a consist patching of the flexible OLED display 200 is guaranteed while achieving precise bending to improve the bending quality and yield rate of the bending process.

The bending fixture 100 of the present invention also has the characteristics of small size and convenient use, and a plurality of the bending fixtures 100 can be arranged side by side, and can be operated by more than one person at a time to improve working efficiency.

It should be understood that in addition to the manual operation, the bending fixture 100 of the present invention can also use various power forms to drive the press and retrieve actions of the convex mold 30, such as electric, pneumatic, hydraulic drive, and so on.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claim of the present invention.

What is claimed is:

1. A bending fixture; applicable to bending flexible organic light-emitting diode (OLED) display; comprising:
a support rack, a concave mold, a convex mold, and a pressing handle;
the support rack comprising: a base, a left plate, and a right plate; the base, the left plate; and the right plate collectively forming a receiving cavity for receiving the concave mold;
the concave mold being disposed with a groove, the groove comprising: a first straight section, a corner section and a second straight section; the corner section having an arc shape; the first straight section being connected to the corner section and tangent to the corner section, the second straight section being connected to the corner section and tangent to the corner section;
an angle between the first straight section and the second straight section being a bending angle of the flexible OLED display;
the convex mold having a convex portion, the convex portion having a third straight section corresponding to the first straight section, a fourth straight section corresponding to the second straight section, and a rounded corner section corresponding to the corner section; the third straight section being connected to the fourth straight section through the rounded corner section;
the pressing handle being connected to the convex mold and used to hold the convex mold during bending to ensure that the convex mold extending into the groove and pressed correctly into place.

2. The bending fixture as claimed in claim 1, wherein the first straight section is parallel to the second straight section, and the arc shape of the corner section is a semicircle.

3. The bending fixture as claimed in claim 2, wherein the number of the concave mold is a plurality, and the plurality of concave molds have corner sections with different radii, all the plurality of concave molds have appearances matching the shape of the receiving cavity so that each of the plurality of the concave molds can be placed inside the receiving cavity according to the radius corresponding to the bending radius of the flexible OLED display.

4. The bending fixture as claimed in claim 3, wherein the corner section of the concave mold has a radius of 1 mm-3 mm.

5. The bending fixture as claimed in claim 4, wherein the groove is disposed at a first plane of the concave mold, and a right-angled edge formed by the groove and the first plane is rounded.

6. The bending fixture as claimed in claim 5, wherein the groove penetrates through the concave mold; in a groove length direction, the concave mold provides at the first plane an against surface perpendicular to the groove length direction, for pushing against the flexible OLED display during bending to maintain the bending line of the flexible OLED display perpendicular to borders of the OLED display.

7. The bending fixture as claimed in claim 1, wherein the number of the concave mold is a plurality, and the first straight sections and the second straight sections of the plurality of concave molds form different intersection angle, all the plurality of concave molds have appearances matching the shape of the receiving cavity so that each of the plurality of the concave molds can be placed inside the receiving cavity according to the radius corresponding to the bending radius of the flexible OLED display.

8. The bending fixture as claimed in claim 1, wherein an enhanced rib is disposed respectively between the base and the left plate, and between the base and the right plate to enhance support.

9. The bending fixture as claimed in claim 1, wherein the pressing handle comprises a sliding portion, the sliding portion slides on a sliding track disposed on the support rack, the sliding portion drives the convex mold to move in and out with respect to the concave mold to achieve bending and releasing motions.

10. The bending fixture as claimed in claim 9, wherein the pressing handle comprises a rotation portion, the rotation portion is rotatably connected to a fulcrum on the support rack, and the sliding portion is disposed on the rotation portion, and a bending handle is disposed at a direction extended from the fulcrum extends to a connection point between the sliding portion and the rotation portion.
